(19) United States
(12) Patent Application Publication
(10) Pub. No.: US 2026/0241422 A1
(43) Pub. Date: Aug. 20, 2026

(54) SYSTEM AND METHOD FOR CLEANING OF TRANSMISSION ELECTRON MICROSCOPE CHAMBER

(71) Applicant: IBSS Group, Inc., South San Francisco, CA (US)

(72) Inventors: Lua (Larry) Tran, South San Francisco, CA (US); Vince Carlino, South San Francisco, CA (US)

(21) Appl. No.: 19/058,545

(22) Filed: Feb. 20, 2025

(51) Int. Cl. B08B 7/00; H01J 37/26

(52) U.S. Cl. CPC B08B 7/0035; H01J 37/261; H01J 2237/022

(57) ABSTRACT

A system and a method for introducing reactive species into a transmission electron microscope (TEM) for cleaning, the TEM maintaining an internal vacuum environment and having a specimen port for introducing a specimen into the TEM for imaging. The system includes (a) a plasma generating device having an output conduit for supplying the reactive species; (b) a pipe having (i) a first end which is coupled in a vacuum sealed manner to the output conduit to receive the reactive species; (ii) a second end inserted through the specimen port into the TEM to release the received reactive species; and (iii) one or more polymer vacuum rings each provided on an outer surface of the pipe to prevent breaching of the TEM's internal vacuum environment; and (c) a support structure for securing the system to the TEM during cleaning.

### BACKGROUND OF THE INVENTION

### 1. Field of the Invention

The present invention relates to cleaning a high-vacuum chamber in a transmission electron microscope (TEM), e.g., a chamber housing the objective lens) using low-energy reactive species in a plasma state.

### 2. Discussion of the Related Art

A transmission electron microscope (TEM) operates in a high vacuum (e.g., 10⁻⁴ to 10⁻⁷ Pa or higher) environment and must be maintained in a contamination-free condition. Contamination may enter the internal environment of the TEM when specimens are introduced for examination in the TEM. FIG. 1 is a cross-section of typical TEM 100, showing various functional components relevant to the present invention. In a TEM, an electron emission source provides a stream of electrons (“electron probe”) which travels through various precisely aligned apertures. In each aperture, the electron prob is focused by an electric field created by a respective electromagnetic lens. The electron probe is terminated at a screen (e.g., a fluorescent screen), where an image is formed for viewing or recording.

One or more pumping systems (not shown in FIG. 1) evacuate the various chambers of TEM 100 to an operational low pressure (e.g., 10⁻⁴ Pa) or vacuum condition, to avoid unintended interactions between the electron probe and the gaseous atoms in the internal environment of the TEM. As shown in FIG. 1, TEM 100 includes electron gun 101, which is an electron emission device that generates the electron probe. The electron probe is first collimated at condenser aperture 102 by condenser lens or lenses 112. In objective aperture 111, the collimated electron probe is focused by objective lens 110, which is then directed to be incident on a specimen under examination. The specimen is introduced into TEM 100 through specimen port 103 and secured at position 114. The specimen scatters the electron probe into a diffraction pattern resulting from its atomic or molecular structure.

The diffraction pattern in the scattered electron probe is processed in intermediate aperture 104 by diffraction lens 111 and intermediate lens 108, where the diffraction pattern has its focusing positions adjusted and magnified. The electron probe is then projected onto fluorescent screen 106 by projector lens 107 to form an image that can be viewed using binoculars 105 or recorded in image recording system 113.

In some TEMs, such as TEM 100, a specimen is introduced by a specimen holder through specimen port 103. Thus, the TEM cannot be permanently vacuum sealed. Air locks are provided between the entry point (i.e., specimen port 103) and the specimen target position in the objective aperture (e.g., position 114 in objective aperture 111), such that any loss of vacuum at any part of TEM 100 due to the introduction of the specimen is significantly reduced. The portion of the TEM between specimen port 103 and position 114 is shielded to minimize the specimen holder from exposure to radiation from the electron probe. Once inserted into the TEM, the sample is manipulated to locate and orientate the region of interest in the specimen to the electron probe. To that end, the TEM provides a goniometer with electromechanical manipulative mechanisms for accurate placement and orientation of the specimen for proper exposure to the electron probe.

FIG. 2 shows single-axis tilt sample holder 200 for insertion into a TEM goniometer. Tilting of the sample holder is achieved by rotating the entire goniometer. As shown in FIG. 2, sample holder 200 includes cylindrical rod 205 attached to knob 201. Knob 201 is sized and configured to allow manual manipulation by a user, while resting snugly on an external wall of the TEM. Cylindrical rod 205, preferably a brass or stainless-steel rod, includes one or more polymer vacuum rings 202 attached. Attached to the free end of cylindrical rod 205 is an extension with opening 204, which is sized for accommodating a circular mesh or grid on which the sample would be placed. On cylindrical rod 205 is provided one or more pins 203 that may be used to activate or deactivate microswitches along the insertion conduit. For example, one mechanism may activate evacuation of the insertion conduit, so that the sample may move into the objective aperture with minimum disturbance to the vacuum conditions in the apertures along the electron probe's path. Polymer vacuum rings 203 form air locks that prevent breach of the vacuum conditions in these apertures through the insertion conduit.

Inevitably, as samples are introduced and removed from the TEM, contamination is introduced into the objective aperture from the samples themselves and from the external environment. The contaminants may accumulate on the inside surfaces of the TEM. The presence of the contaminants may affect the quality of the TEM images. In the prior art, a process known as “baking” is used to remove volatile hydrocarbon or other carbonaceous contaminants. Baking involves raising the TEM to a high temperature under a high vacuum condition for an extended time period (e.g., 24 hours or more). The high temperature ashes the contaminants, which are then evacuated by the vacuum system as gaseous species (e.g., steam and carbon dioxide). Because of the prolonged exposure to high temperature, recalibration and realignment of the various electromagnetic lenses along the various apertures are typically required.

### SUMMARY

A system and a method for introducing reactive species into a transmission electron microscope (TEM) for cleaning, the TEM maintaining an internal vacuum environment and having a specimen port for introducing a specimen into the TEM for imaging. The system includes (a) a plasma generating device having an output conduit for supplying the reactive species; (b) a pipe having (i) a first end which is coupled in a vacuum sealed manner to the output conduit to receive the reactive species; (ii) a second end inserted through the specimen port into the TEM to release the received reactive species; and (iii) one or more polymer vacuum rings each provided on an outer surface of the pipe to prevent breaching of the TEM's internal vacuum environment; and (c) a support structure for securing the system to the TEM during cleaning. The gaseous reactive species may be in a plasma state.

In one embodiment, the pipe is part of a plasma cleaning inlet assembly, which further includes an attachment piece for securely mounting the plasma cleaning inlet assembly to an outer wall of the TEM.

In one embodiment, the support structure is configured for supporting the plasma generating device. The support structure may be extensible for height adjustment.

In one embodiment, the gaseous reactive species provided at the shielded chamber have energy less than 100 eV, and preferably less than 30 eV. The gaseous reactive species are selected for reacting with hydrocarbon or carbonaceous contaminants inside the TEM. The products of the reaction includes moisture and volatile products, which are evacuated out of the TEM through the vacuum system in the TEM.

These and other advantages, aspects, and novel features of the present invention, as well as details of an illustrated embodiment thereof, will be more fully understood upon consideration of the following description and drawings.

### BRIEF DESCRIPTION OF THE DRAWINGS

FIG. 1 is a cross-section of typical TEM 100, showing various functional components relevant to the present invention.

FIG. 2 shows single-axis tilt sample holder 200 for insertion into a TEM goniometer.

FIG. 3 shows plasma cleaning system 300 for use in a TEM, in accordance with one embodiment of the present invention.

FIG. 4 shows plasma cleaning system 300 deployed to clean TEM 100 of FIG. 1, in accordance with one embodiment of the present invention; FIG. 4 also includes an inset that shows in greater detail cylindrical pipe 303 being incorporated into plasma cleaning inlet assembly 406 for attachment at specimen port 103.

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily drawn to scale.

### DETAILED DESCRIPTION OF THE PREFERRED EMBODIMENTS

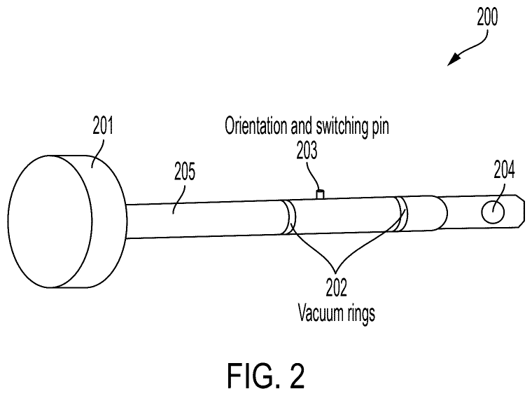

According to one embodiment of the present invention, hydrocarbon or carbonaceous contaminants in a TEM may be removed at low temperature (e.g., room temperature) by low-energy reactive species in a plasma state. With a plasma source operating at 100 watts, for example, such low-energy reactive species at 30 centimeters downstream from source may have an energy of 100 eV or less, such as 30 eV. In some embodiments, a cylindrical pipe with one end attached to a plasma source releases the low-energy reactive species at its other end, the cylindrical pipe being adapted be introduced into the TEM in place of the cylindrical rod (such as cylindrical rod 205 in FIG. 2) of a TEM specimen holder. These low-energy reactive plasma species are selected for their quality of not leaving residuals or radiation that would impair or damage subsequent specimens or the TEM itself, nor interfere with subsequent TEM image acquisition.

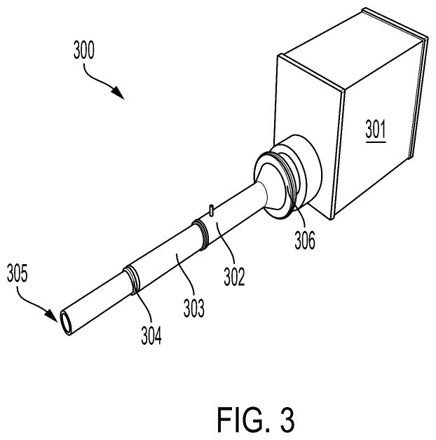

FIG. 3 shows plasma cleaning system 300 for use in a TEM, in accordance with one embodiment of the present invention. As shown in FIG. 3, plasma source 301 generates and delivers gaseous reactive species into cylindrical pipe 303, which has one end (“plasma source end”) 302 attached and hermetically sealed at an output conduit in plasma output assembly 306 of plasma source 301. Plasma source 301 may be, for example, the plasma generation system described in U.S. patent application, Ser. No. 18/395,115, entitled “Structure And Method For Concentrating Plasma For Injection Into A Reaction Chamber,” filed on Dec. 22, 2023. The disclosure of the '115 patent application is hereby incorporated by reference in its entirety to provide relevant information and context.

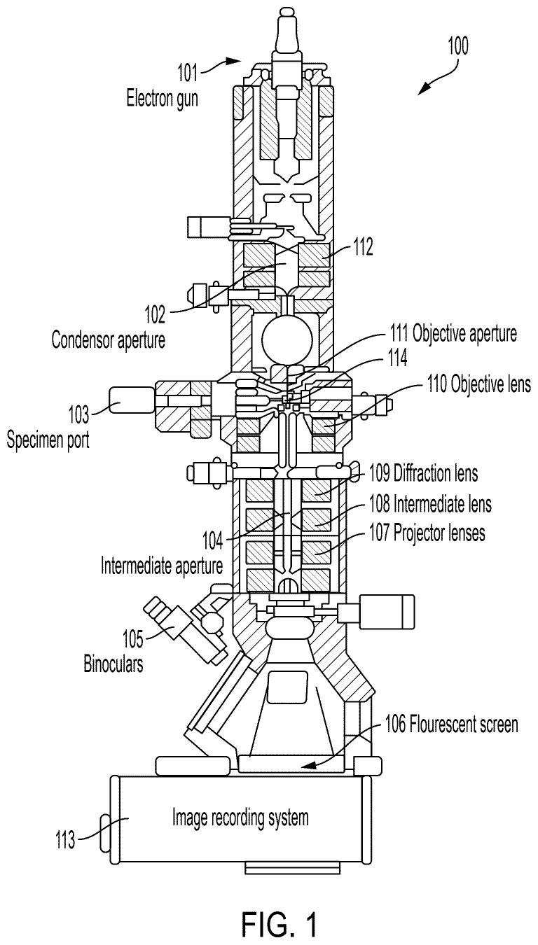

In one embodiment, cylindrical pipe 303 is incorporated into a specimen holder-like assembly to be introduced into the TEM through a specimen port of a TEM (e.g., specimen port 103 in TEM 100 of FIG. 1). One or more polymer vacuum rings (e.g., polymer vacuum ring 304) form air locks to prevent a breach of the vacuum system in the TEM. Distal end 305 of cylindrical pipe 305 is open, such that the low-energy reactive species from plasma source 301 is introduced into the TEM at full bore (i.e., the inner diameter cross-section area). For systems that require pins to be provided in the specimen holder for operating any control mechanism of the TEM (e.g., microswitches) along the insertion conduit of the specimen port, pins similar to pins 203 of cylindrical rod 205 of FIG. 2 may be provided along cylindrical pipe 303.

This configuration of plasma cleaning system 300 is believed to more efficiently and more effectively deliver the gaseous reactive species than, for example, through a series of small openings near distal end 304 of cylindrical pipe 303. The gaseous reactive species remaining in the plasma state depends on the distance between output assembly 306 and distal end 305. The configuration in which a series of small openings are provided near distal end 305 is believed to deliver substantially less gaseous reactive species in the plasma state.

The gaseous reactive species react with the hydrocarbon or carbonaceous contaminants inside TEM 100 to form moisture and volatile products, such as carbon oxides (e.g., carbon dioxide), which are then evacuated out of TEM 100 through its vacuum system. This reaction is known to those of ordinary skill in the art as “ashing.” Plasma cleaning system 300 is believed able to achieve in two hours the same cleaning achieved in 8 hours of baking in the prior art.

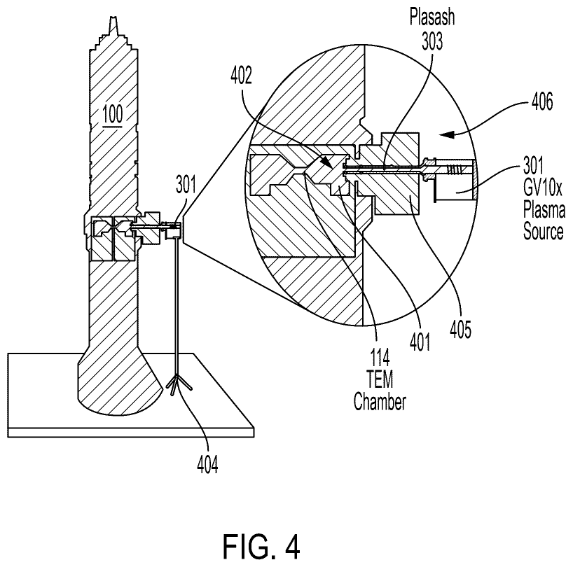

FIG. 4 shows plasma cleaning system 300 deployed to clean TEM 100 of FIG. 1, in accordance with one embodiment of the present invention; FIG. 4 also includes an inset that shows in greater detail cylindrical pipe 303 being incorporated into plasma cleaning inlet assembly 406 for attachment to an outer wall of TEM 100 at specimen port 103. As shown in FIG. 4, plasma cleaning system 300 now includes support structure 404, which provides stability to plasma source 301 as the plasma cleaning process progresses. Support structure 404 may be, for example, a stand with an extensible body for height adjustment (e.g., with a telescoping support stand).

The inset of FIG. 4 shows that cylindrical pipe 303 is incorporated into plasma cleaning inlet assembly 406, which has wall attachment piece 405 that attaches snugly to an outer wall of TEM 100 at specimen port 103, in substantially the same way as knob 201 of single-axis tilt sample holder 200 of FIG. 2 attaches to that outer wall. In the embodiment shown in FIG. 4, unlike cylindrical rod 205 of FIG. 2, cylindrical pipe 303 need not extend all the way to specimen position 114, but with distal end 305 open to shielded chamber 402 of TEM 100 inside specimen port 103 at an appropriate position in shielded chamber 402. In this configuration, plasma cleaning system 300 provides low-energy reactive plasma species to clean the objective lens, including its pole pieces, and the liners at the inner walls of the objective aperture, and of the other apertures along the path of the electron probe.

The above detailed description is provided to illustrate specific embodiments of the present invention and is not intended to be limiting. Numerous variations and modifications within the scope of the present invention are possible. The present invention is set forth in the accompanying claims.

We claim:

1. A system for introducing gaseous reactive species into a transmission electron microscope (TEM) for cleaning, the TEM maintaining an internal vacuum environment and having a specimen port for introducing a specimen into the TEM for imaging, comprising:
a plasma generating device having an output conduit for supplying the gaseous reactive species;
a pipe comprising:
a first end which is coupled in a vacuum-sealed manner to the output conduit of the plasma generating device to receive the reactive species;
a second end inserted through the specimen port into the TEM to release the received reactive species; and
one or more polymer vacuum rings each provided on an outer surface of the pipe to prevent breaching of the TEM's internal vacuum environment; and
a support structure for securing the system to the TEM during cleaning.

2. The system of claim 1, wherein the support structure is configured for supporting the plasma generating device.

3. The system of claim 2, wherein the support structure is extensible for height adjustment.

4. The system of claim 1, wherein the pipe is part of a plasma cleaning inlet assembly, which further comprises an attachment piece for securely mounting the plasma cleaning inlet assembly to an outer wall of the TEM.

5. The system of claim 4, wherein the gaseous reactive species are in a plasma state.

6. The system of claim 1, wherein the second end of the pipe opens into a shielded chamber of the TEM.

7. The system of claim 6, wherein a portion of the pipe extends into the shielded chamber of the TEM, and wherein that portion of the pipe includes one or more pins positioned for operating a control mechanism of the TEM within the shield chamber.

8. The system of claim 6, wherein the second end of the pipe opens into the shielded chamber in full bore.

9. The system of claim 6, wherein the gaseous reactive species provided at the shielded chamber have energy less than 100 eV.

10. The system of claim 6, wherein the gaseous reactive species provided at the shielded chamber have energy less than 30 eV.

11. The system of claim 1, wherein the gaseous reactive species react with hydrocarbon or carbonaceous contaminants inside the TEM.

12. The system of claim 1, wherein the gaseous reactive species react with hydrocarbon or carbonaceous contaminants inside the TEM, which products are evacuated out of the TEM.

13. The system of claim 12, wherein the products comprise moisture and one or more volatile products.

14. The system of claim 12, wherein the products are evacuated out of the TEM.

15. A method for introducing gaseous reactive species into a transmission electron microscope (TEM) for cleaning, the TEM maintaining an internal vacuum environment and having a specimen port for introducing a specimen into the TEM for imaging, comprising:
(1) connecting the specimen port of the TEM to a system that includes:
(a) a plasma generating device that includes an output conduit for supplying the gaseous reactive species; and
(b) a pipe that includes: (i) a first end which is coupled in a vacuum-sealed manner to the output conduit of the plasma generating device to receive the reactive species; (ii) a second end inserted through the specimen port into the TEM to release the received reactive species; and (iii) one or more polymer vacuum rings each provided on an outer surface of the pipe to prevent breaching of the TEM's internal vacuum environment; and
(2) providing a support structure for securing the system to the TEM during cleaning.

16. The method of claim 15, wherein the support structure is configured for supporting the plasma generating device.

17. The method of claim 15, wherein the support structure is extensible for height adjustment.

18. The method of claim 15, wherein the pipe is part of a plasma cleaning inlet assembly, which further comprises an attachment piece for securely mounting the plasma cleaning inlet assembly to an outer wall of the TEM.

19. The method of claim 18, wherein the gaseous reactive species are in a plasma state.

20. The method of claim 15, wherein the second end of the pipe opens into a shielded chamber of the TEM.

21. The method of claim 20, wherein a portion of the pipe extends into the shielded chamber of the TEM, and wherein that portion of the pipe includes one or more pins positioned for operating a control mechanism of the TEM within the shield chamber.

22. The method of claim 20, wherein the second end of the pipe opens into the shielded chamber in full bore.

23. The method of claim 20, wherein the gaseous reactive species provided at the shielded chamber have energy less than 100 eV.

24. The method of claim 20, wherein the gaseous reactive species provided at the shielded chamber have energy less than 30 eV.

25. The method of claim 15, wherein the gaseous reactive species react with hydrocarbon or carbonaceous contaminants inside the TEM.

26. The method of claim 15, wherein the gaseous reactive species react with hydrocarbon or carbonaceous contaminants inside the TEM, which products are evacuated out of the TEM.

27. The method of claim 26, wherein the products comprise moisture and one or more volatile products.

28. The method of claim 26, wherein the products are evacuated out of the TEM.
